(19) United States
(12) Patent Application Publication
(10) Pub. No.: US 2012/0249176 A1
(43) Pub. Date: Oct. 4, 2012

(54) TEST STRUCTURE AND MEASUREMENT METHOD THEREOF

(75) Inventors: Heng-Chieh Chien, New Taipei City (TW); Ra-Min Tain, New Taipei City (TW); John H. Lau, Taipei City (TW); Yu-Lin Chao, Hsinchu City (TW); Ming-Ji Dai, Hsinchu City (TW)

(73) Assignee: INDUSTRIAL TECHNOLOGY RESEARCH INSTITUTE, Hsinchu (TW)

(21) Appl. No.: 13/169,051

(22) Filed: Jun. 27, 2011

(30) Foreign Application Priority Data
Mar. 30, 2011 (TW) 100111062

(51) Int. Cl. G01R 31/00

(52) U.S. Cl. 324/756.02

(57) ABSTRACT

A test structure including a substrate, at least one conductive plug, a first conductive trace and a second conductive trace is provided. The substrate has a first area and a second area. The at lest one conductive plug is disposed in the substrate in the first area, wherein the conductive plug does not penetrate through the substrate.

The first conductive trace is disposed on the conductive plug and on the substrate in the first area. The second conductive trace is disposed on the substrate in the second area. It is noted that the first conductive trace and the second conductive trace have the same material and the same shape. A measurement method of the above-mentioned test structure is also provided.

### CROSS-REFERENCE TO RELATED APPLICATION

This application claims the priority benefit of Taiwan application serial no. 100111062, filed Mar. 30, 2011. The entirety of the above-mentioned patent application is hereby incorporated by reference herein and made a part of this specification.

### TECHNICAL FIELD

The disclosure relates to a test structure for evaluating the thermal performance of through silicon vias (TSVs) and a measurement method thereof.

### BACKGROUND

Three-dimensional (3D) IC integration is a desirable technology for many SiP (System in a Package) design because of the advantages of smaller size, shorter signal routing, and reduced wiring density. Recently, the development of 3D IC integration has been accelerated and its stage has been changed from the research level for limited production to the investigation level with a view to mass production. Because ultra-thin chip and stacked structure, hot spot and the heat accumulated in the middle chip layers severely influence the stacked chips reliability. In fact, thermal problem is one of the most important issues for the 3D IC design and application.

TSV (Through Silicon Via) is a favorable technology for the 3D IC by replacing the conventional edge wiring with vertical connections through the body of the chips/interposers. Except for enhancing signal processing, TSV also can effectively dissipate the accumulated heat in the stacked chip due to shorter heat transport path and higher thermal conductivity of its filled copper. However, seams in the TSV can damage its thermal performance significantly and therefore lose its benefit for thermal management.

In this disclosure, a TSV test structure and the coupled measurement method to determine TSVs' integrity by using thermal technique are described. The TSV test structure and the coupled method can diagnose TSVs' integrity and their thermal performance before the wafer-thinning process. Therefore, the measurement results can avoid unnecessary wastes for cost and time by taking out the disqualified wafer in advance.

### SUMMARY

The disclosure provides a test structure including a substrate, at least one conductive plug, a first conductive trace and a second conductive trace. The at least one conductive plug is disposed in the substrate, and the first conductive trace is disposed on the conductive plug. The second conductive trace is disposed on the substrate, wherein the first conductive trace and the second conductive trace have the same material and the same shape.

The disclosure further provides a measurement method of a test structure. A test sample is provided, wherein the test sample includes a substrate, at least one conductive plug, a first conductive trace and a second conductive trace. A first temperature coefficient of resistivity (TCR) curve of the first conductive trace and a second TCR curve of the second conductive trace are established. A first current (I₁) is applied to the first conductive trace to measure a first voltage (V₁) of the first conductive trace, and a second current (I₂) is applied to the second conductive trace to measure a second voltage (V₂) of the second conductive trace. Therefore, a first thermal power (P₁) and a first electrical resistance (Ω₁) of the first conductive trace and a second thermal power (P₂) and a second electrical resistance (Ω₂) of the second conductive trace are obtained. A first temperature (T₁) of the first conductive trace is obtained according to the first electrical resistance (Ω₁) using the first TCR curve, and a second temperature (T₂) of the second conductive trace is obtained according to the second electrical resistance (Ω₂) using the second TCR curve. A backside temperature (T_{c}) of the substrate can be measured by conventional temperature sensors, such as thermocouple, thermistor or RTD (resistance temperature detector). A first thermal resistance (R₁) of the first conductive trace is obtained from the first temperature (T₁), the first thermal power (P₁) and the backside temperature (T_{c}). The second thermal resistance (R₂) of the second conductive trace is obtained from the second temperature (T₂), the second thermal power (P₂) and the backside temperature (T_{c}). Wherein the thermal performance of the conductive plug is obtained from a thermal resistance difference between the first thermal resistance (R₁) and the second thermal resistance (R₂).

Several exemplary embodiments accompanied with figures are described in detail below to further describe the invention in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 schematically illustrates a perspective view of a test structure according to a first embodiment of the disclosure.

FIGS. 1A and 1B schematically illustrate cross-sectional views respectively along A-A′ line and B-B′ line of FIG. 1.

FIG. 2 schematically illustrates a perspective view of another test structure according to the first embodiment of the disclosure.

FIG. 3 schematically illustrates a perspective view of a test structure according to a second embodiment of the disclosure.

FIG. 4 schematically illustrates a perspective view of a test structure according to a third embodiment of the disclosure.

FIG. 5 illustrates a process flow of a measurement method of a test structure according to an embodiment of the disclosure.

FIGS. 6A to 6D each schematically illustrate a cross-sectional view of a test sample on a test platen.

FIG. 7 schematically illustrates a first TCR curve of a first conductive trace.

FIG. 8 illustrates a graph of thermal resistance difference vs. sample number, wherein the solid line is generated by using computational simulation or measuring a single qualified and completed sample, and the dash line corresponds to the minimal integrity-acceptable level.

FIG. 9 illustrates a graph of thermal resistance difference vs. sample number, wherein the slash region represents a qualified range generated by measuring large-scale samples.

### DETAILED DESCRIPTION OF DISCLOSED EMBODIMENTS

The test structure of the disclosure and the measurement method thereof can be applied to through silicon vias (TSVs) of a 3DIC package, vias of a ceramics substrate or etc.

The disclosure provides a test structure and a coupled measurement method thereof, in which the TSVs integrity can be determined as good or no good by using an in-line test, and further, the effective thermal conductivity of the embedded TSVs can be calculated from the measured results.

### First Embodiment

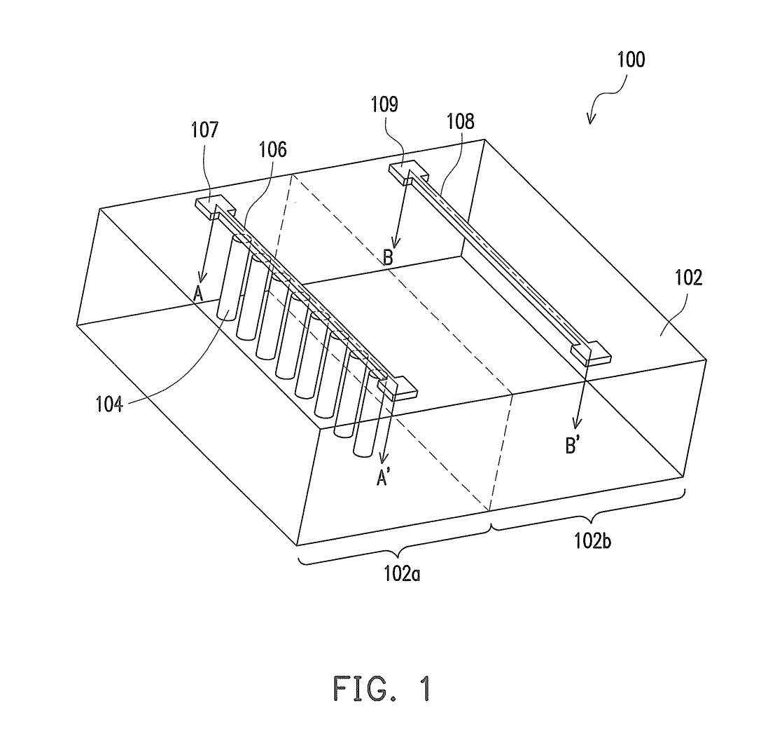

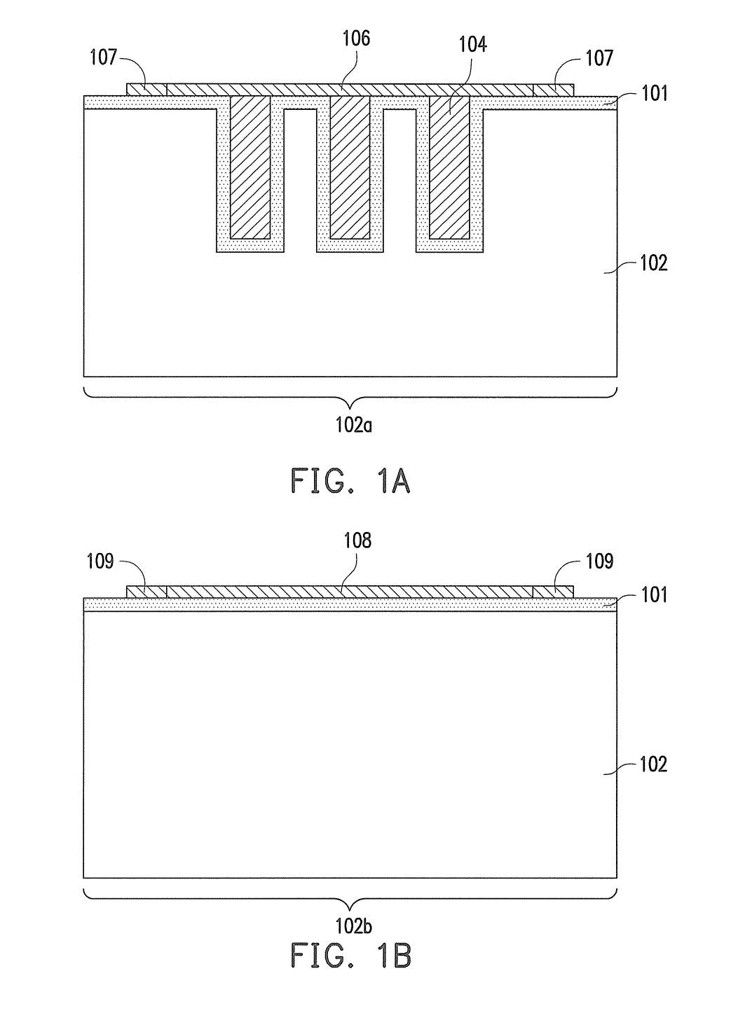

FIG. 1 schematically illustrates a perspective view of a test structure according to a first embodiment of the disclosure. FIGS. 1A and 1B schematically illustrate cross-sectional views respectively along A-A′ line and B-B′ line of FIG. 1.

Referring to FIGS. 1, 1A and 1B, a test structure 100 includes a substrate 102, at least one conductive plug 104, a first conductive trace 106 and a second conductive trace 108. The substrate 102 has a first area 102a and a second area 102b. The first area 102a and the second area 102b are located in a scribe line or in a suitable region. A material of the substrate 102 includes silicon. The first area 102a and the second area 102b are adjacent to each other. The first conductive trace 106 and the second conductive trace 108 are arranged correspondingly. Further, the first conductive trace 106 and the second conductive trace 108 are arranged in parallel. The first conductive trace 106 and the second conductive trace 108 are adjacent to each other.

The at least one conductive plug 104 is disposed in the substrate 102 in the first area 102a. A material of the conductive plugs 104 includes metal, such as tungsten or copper. It is noted that each conductive plug 104 does not penetrate through the substrate 102. That is, the test structure 100 of the disclosure can be applied prior to the thinning process of the substrate 102. In an embodiment, when substrate 102 is a silicon substrate, each conductive plug 104 is a through silicon via (TSV), for example.

In the above embodiment, eight conductive plugs 104 are provided for illustration purposes. However, the number of the conductive plugs 104 is not limited by the disclosure. People skilled in the art should appreciate that the number of the conductive plugs 104 can be one or more.

The first conductive trace 106 is disposed on the conductive plugs 104 and on the substrate 102 in the first area 102a. That is, the first conductive trace 106 is disposed on a surface of the substrate 102 in the first area 102a. In this embodiment, the first conductive trace 106 is physically connected to the conductive plugs 104. A material of the first conductive trace 106 includes metal, such as copper, aluminium or an alloy thereof.

The second conductive trace 108 is disposed on a surface of the substrate 102 in the second area 102b. A material of the second conductive trace 108 includes metal, such as copper, aluminium or an alloy thereof. The first conductive trace 106 and the second conductive trace 108 include the same material.

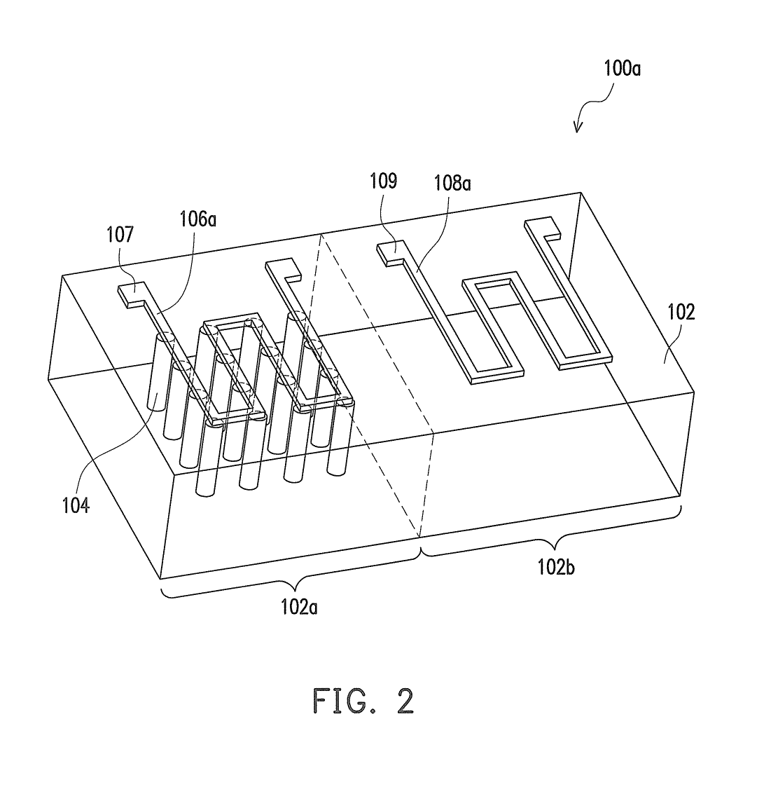

In addition, the first conductive trace 106 and the second conductive trace 108 have the same shape and metal material. In this embodiment, the conductive plugs 104 are arranged in a line, so that the first conductive trace 106 and the second conductive trace 108 are linear, as shown in FIG. 1. However, the disclosure is not limited thereto. In another embodiment, when the conductive plugs 104 are arranged in a snake shape, the corresponding first conductive trace 106 and the second conductive trace 108 are serpentine, as shown in FIG. 2. The serpentine design meets the requirement for small area. It is for sure that the conductive plugs, the first conductive trace and the second conductive trace can be arranged in any shape upon the design requirement.

In an embodiment, the test structure 100 can further include an insulating layer 101. The insulating layer 101 is disposed between each conductive plug 104 and the substrate 102, between the first conductive trace 106 and the substrate 102 and between the second conductive trace 108 and the substrate 102. A material of the insulating layer 101 includes tetraethosiloxane (TEOS) silicon oxide, silicon nitride or silicon oxynitride.

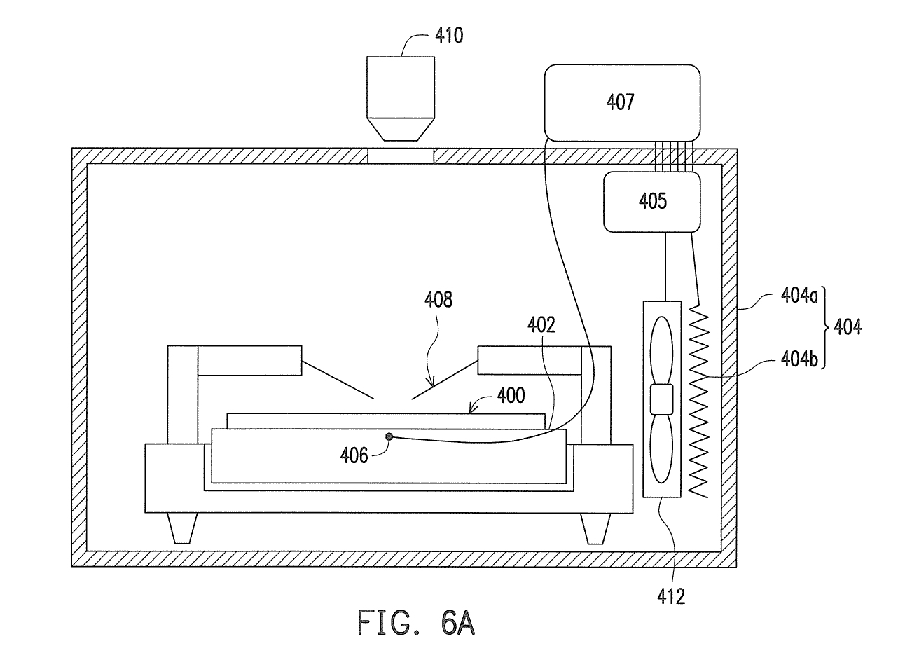

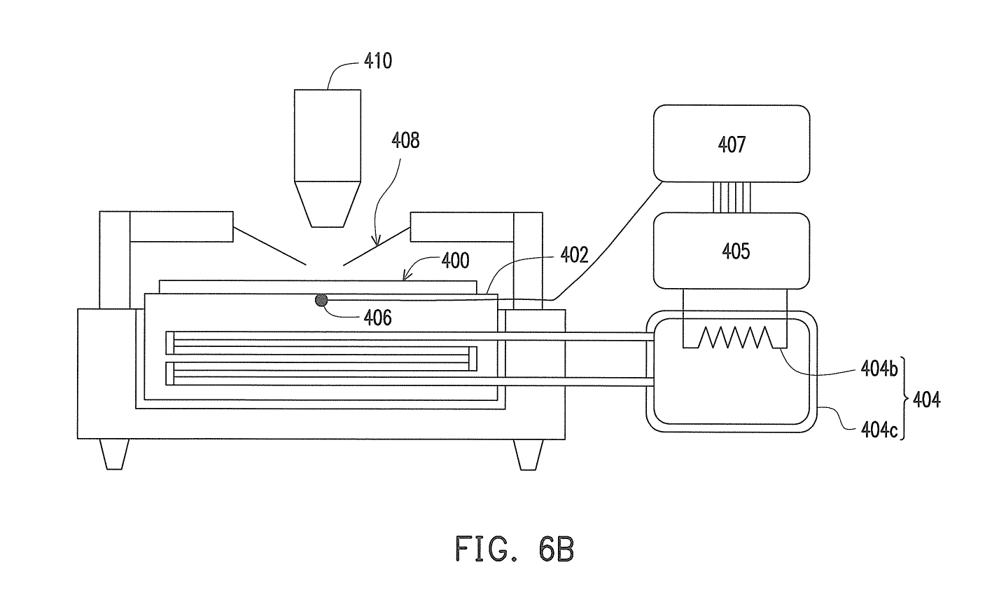

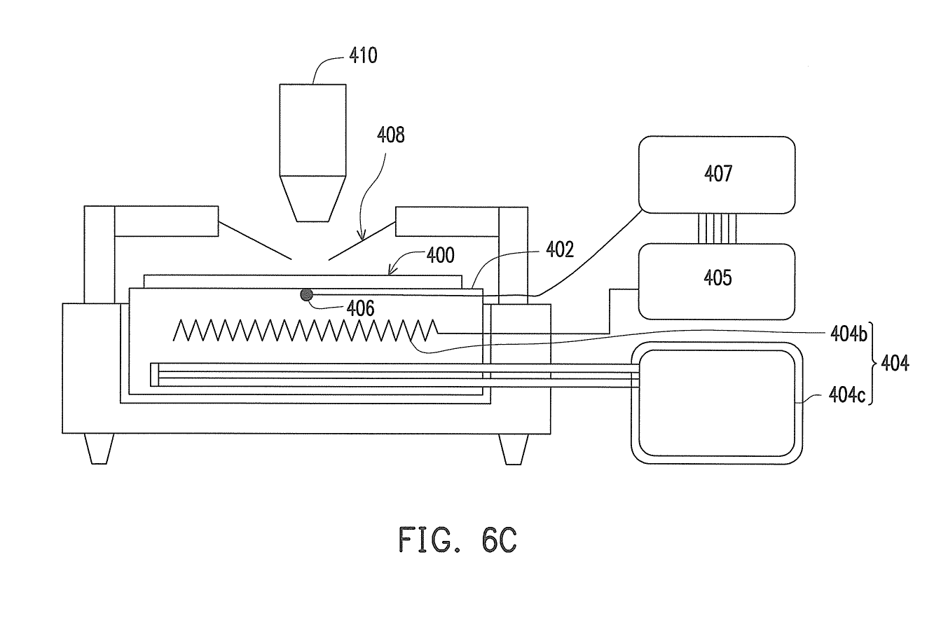

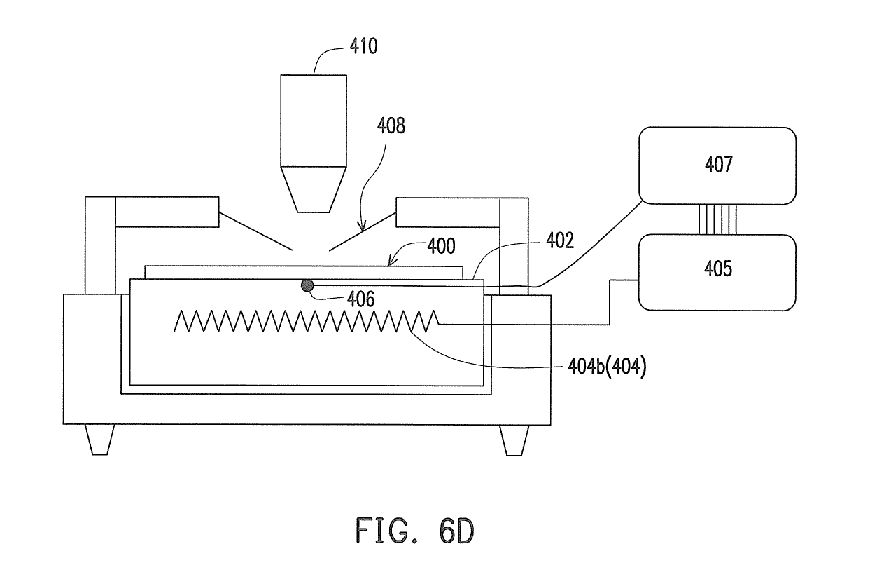

Besides, the first conductive trace 106 and the second conductive trace 108 each have at least one test pad, and one of the measurement tools in the embodiments of FIGS. 6A to 6D can be used to measure thermal resistances of the first conductive trace 106 and the second conductive trace 108. In this embodiment, the first conductive trace 106 has two test pads 107 respectively at its ends thereof, and the second conductive trace 108 has two test pads 109 respectively at its ends thereof. However, the disclosure is not limited thereto. In another embodiment, the first conductive trace 106 and the second conductive trace 108 each can have a plurality of test pads upon the design requirement.

In view of the foregoing, in the test structure 100 of the disclosure, different components are disposed in the first area 102a and the second area 102b of the substrate 102, the at least one conductive plug 104 and the first conductive trace 106 are disposed in the first area 102a, and only the second conductive trace 108 is disposed in the second area 102b. The first conductive trace 106 and the second conductive trace 108 have the same material, shape and dimension, so that a thermal resistance difference between the first area 102a and the second area 102b is a thermal resistance of the conductive plug 104. Therefore, the thermal performance of the conductive plugs 104 (e.g. TSVs) can be evaluated prior to the thinning process of the substrate 102. The TSV heat dissipation property can be determined as good or no good in a real time, fast, and convenient manner. Accordingly, the competitive advantage can be easily achieved.

### Second Embodiment

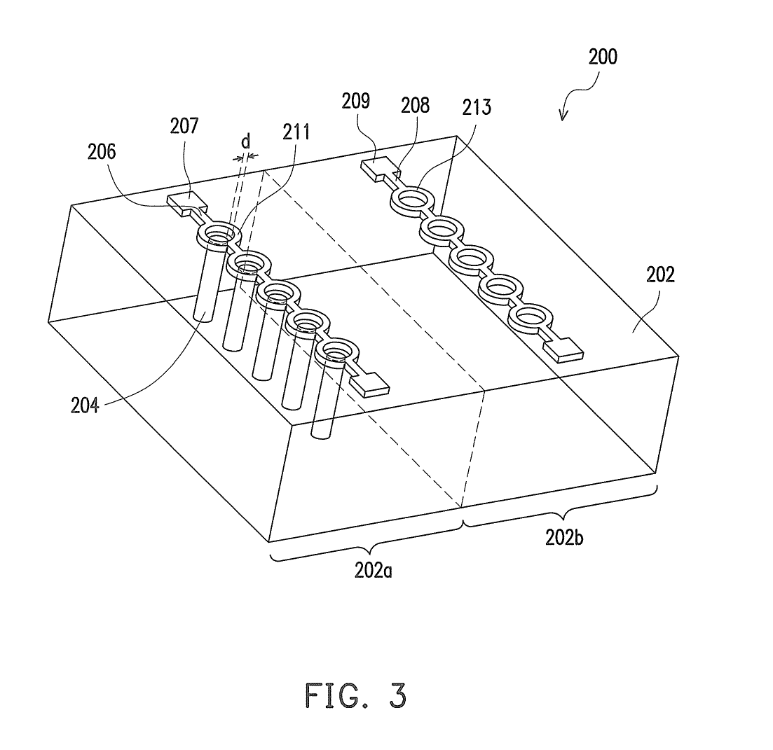

FIG. 3 schematically illustrates a perspective view of a test structure according to a second embodiment of the disclosure. The test structure 200 of the second embodiment is similar to the test structure 100 of the first embodiment, the difference between them is illustrated in the following, and the similarities are not iterated herein.

Referring to FIG. 3, the test structure 200 includes a substrate 202, at least one conductive plug 204, a first conductive trace 206 and a second conductive trace 208. The substrate 202 has a second area 202a and a second area 202b. The first area 202a and the second area 202b are adjacent to each other. The first conductive trace 206 and the second conductive trace 208 are arranged correspondingly. Further, the first conductive trace 206 and the second conductive trace 208 are arranged in parallel. The first conductive trace 206 and the second conductive trace 208 are adjacent to each other.

The first conductive trace 206 is disposed on the conductive plugs 204 and on a surface of the substrate 202 in the first area 202a. It is noted that in this embodiment, the first conductive trace 206 is not physically connected to the conductive plugs 204, and the first conductive trace 206 surrounds the conductive plugs 204. Specifically, the first conductive trace 206 has a plurality of conductive rings 211 and two test pads 207. Each conductive ring 211 surrounds the corresponding conductive plug 204. That is, the central axis of the conductive plug 204 passes through the ring centre of the conductive ring 211, and the shortest distance between the conductive ring 211 and the conductive plug 204 is equal to or less than 10 μm. The test pads 207 are respectively disposed at ends of the first conductive trace 206 and electronically connected to the outmost conductive rings 211. The conductive rings 211 are disposed between the two test pads 207.

The second conductive trace 208 is disposed on a surface of the substrate 202 in the second area 202b. The second conductive trace 208 and the first conductive trace 206 have the same shape. Similarly, the second conductive trace 208 has a plurality of conductive rings 213 and two test pads 209.

In an embodiment, the test structure 200 can further include an insulating layer (not shown). The insulating layer is disposed between each conductive plug 204 and the substrate 202, between the first conductive trace 206 and the substrate 202 and between the second conductive trace 208 and the substrate 202.

### Third Embodiment

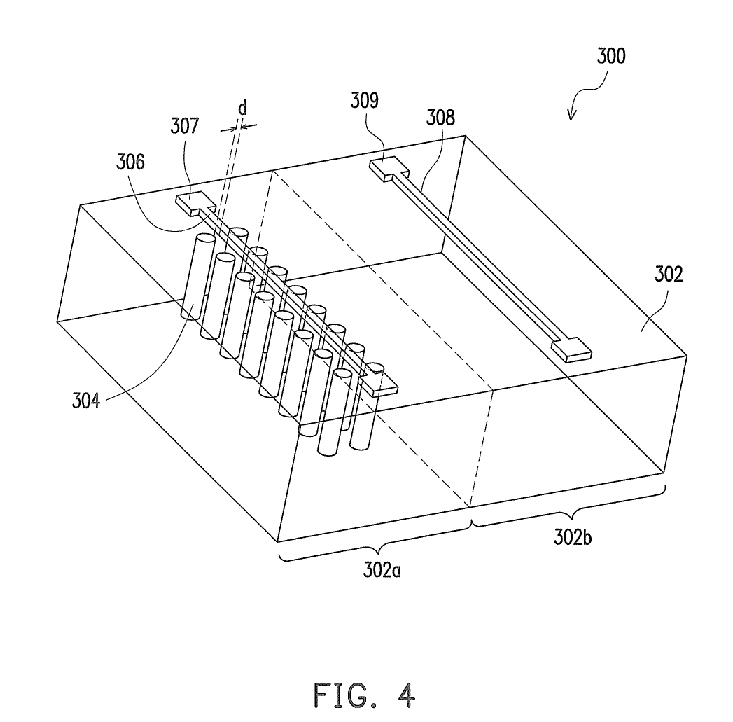

FIG. 4 schematically illustrates a perspective view of a test structure according to a third embodiment of the disclosure. The test structure 300 of the third embodiment is similar to the test structure 200 of the second embodiment, the difference between them is illustrated in the following, and the similarities are not iterated herein.

Referring to FIG. 4, the test structure 300 includes a substrate 302, at least one conductive plug 304, a first conductive trace 306 and a second conductive trace 308. The substrate 302 has a second area 302a and a second area 302b. The first area 302a and the second area 302b are adjacent to each other. The first conductive trace 306 and the second conductive trace 308 are arranged correspondingly. Further, the first conductive trace 306 and the second conductive trace 308 are arranged in parallel. The first conductive trace 306 and the second conductive trace 308 are adjacent to each other.

The first conductive trace 306 is disposed on the conductive plugs 304 and on a surface of the substrate 302 in the first area 302a. It is noted that in this embodiment, the first conductive trace 306 is not physically connected to the conductive plugs 304, the conductive plugs 304 are disposed in the substrate 302 beside the first conductive trace 306, and the shortest distance between the first conductive trace 306 and the corresponding conductive plug 304 is equal to or less than 10 μm. In an embodiment, a plurality of the conductive plugs 304 can be divided to two rows of conductive plugs 304, and the first conductive trace 306 is disposed on a surface of the substrate 302 between the two rows of the conductive plugs 304, as shown in FIG. 4. In another embodiment (not shown), a plurality of the conductive plugs 304 can be divided to a plurality of rows of conductive plugs 304, and the first conductive trace 306 is disposed on a surface of the substrate 302 between the plurality of rows of the conductive plugs 304.

The second conductive trace 308 is disposed on a surface of the substrate 302 in the second area 302b. The second conductive trace 308 and the first conductive trace 306 are linear. Further, the first conductive trace 306 has two test pads 307 respectively at its ends thereof, and the second conductive trace 308 has two test pads 309 respectively at its ends thereof.

In an embodiment, the test structure 300 can further include an insulating layer (not shown). The insulating layer is disposed between each conductive plug 304 and the substrate 302, between the first conductive trace 306 and the substrate 302 and between the second conductive trace 308 and the substrate 302.

The measurement method of the test structure of the disclosure is described in the following. In the test structure of the disclosure, at least one conductive plug is disposed below the first conductive trace while no conductive plug is disposed below the second conductive trace, so that the electrical properties of the first conductive trace and the second conductive trace are different. Accordingly, a thermal resistance difference between the first conductive trace and the second conductive trace can be deduced from an electrical property difference and simple formulae. This thermal resistance difference is a thermal resistance of the at least one conductive plug disposed below the first conductive trace.

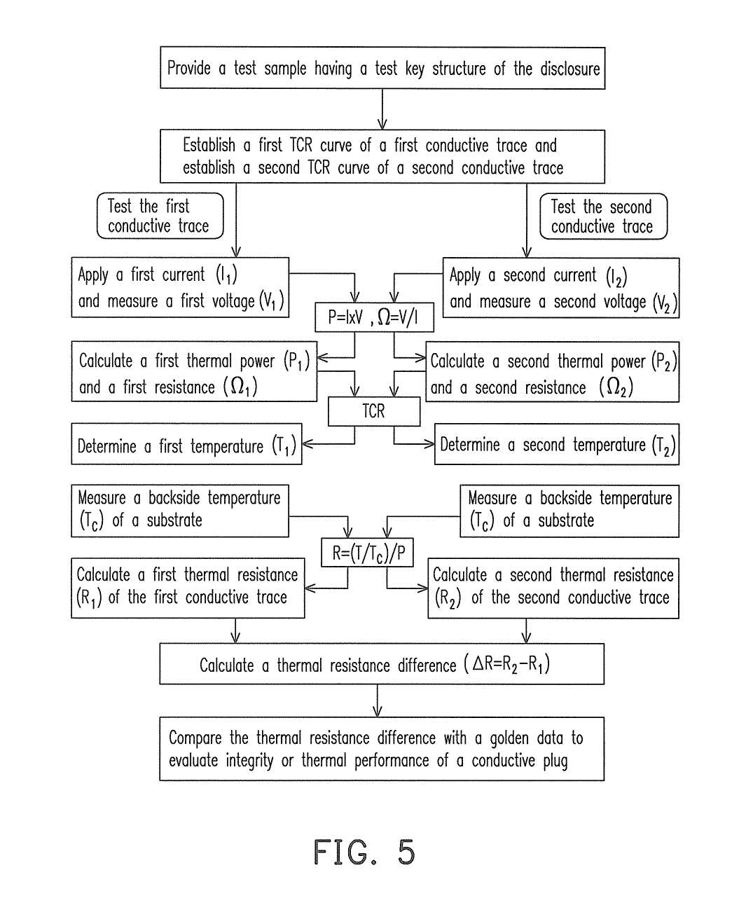

FIG. 5 illustrates a process flow of a measurement method of a test structure according to an embodiment of the disclosure. FIGS. 6A to 6D each schematically illustrate cross-sectional views of a test sample on a test platen. Referring to FIGS. 5 and 6A to 6D, a test sample 400 is provided. The test sample 400 includes one of the test structures shown in FIGS. 1 to 4 or a suitable test structure. The test sample 400 is placed on a test platen 402, and a temperature sensor 406 is disposed in the test platen 402 close to a surface of the test platen 402. The temperature sensor 406 is connected to a controller 407. The controller 407 is a programmable logic controller, for example. The controller 407 is connected to a power supply 405. Besides, a CCD camera 410 is disposed above the test platen 402, so as to determine whether a probe 408 is on a correct position (e.g. a test pad). A temperature controllable member 404 is for changing a temperature of the test platen 402. The temperature controllable member 404 is a thermostat chamber 404a, a hot plate 404b, an oil-bath tank 404c or a combination thereof The examples of the temperature controllable member 404 are illustrated in the following embodiments. However, the scopes of these embodiments are not intended to limit the disclosure. Other examples of the temperature controllable member that can be applied to the disclosure is within the scope and spirit of the disclosure.

In an embodiment, as shown in FIG. 6A, the temperature controllable member 404 includes a thermostat chamber 404a and a hot plate 404b. The thermostat chamber 404a covers the test platen 402. The hot plate 404b is disposed at one side in the thermostat chamber 404a and connected to the power supply 405. A fan 412 is disposed above the hot plate 404b.

In another embodiment, as shown in FIG. 6B, the temperature controllable member 404 includes an oil-bath tank 404c and a hot plate 404b. The oil-bath tank 404c is connected to the test platen 402 and has a pipe extended to the inner of the test platen 402 to provide an appropriate temperature for the test sample 400 or for the surface of the test platen 402. The hot plate 404b is disposed in the oil-bath tank 404c and connected to the power supply 405. A liquid is placed within the oil-bath tank 404c, and the liquid is water, oil or another suitable liquid, for example.

In yet another embodiment, as shown in FIG. 6C, the temperature controllable member 404 includes an oil-bath tank 404c and a hot plate 404b. The oil-bath tank 404c is connected to the test platen 402 and has a pipe extended to the inner of the test platen 402 to help keep the temperature constant. The difference between FIG. 6C and FIG. 6B lies in that the hot plate 404b is disposed inside the test platen 402 to provide an appropriate temperature for the test sample 400 or for the surface of the test platen 402. A liquid is placed within the oil-bath tank 404c, and the liquid is water, oil or another suitable liquid, for example. The oil-bath tank 404c provides a liquid at an appropriate temperature to help the hot plate 404b to control/keep a constant temperature.

In still yet another embodiment, as shown in FIG. 6D, the temperature controllable member 404 includes a hot plate 404b. The hot plate 404b is disposed inside the test platen 402 to provide an appropriate temperature for the test sample 400.

Thereafter, a first temperature coefficient of resistivity (TCR) curve of the first conductive trace and a second TCR curve of the second conductive trace are established. A method of establishing the first TCR curve and the second TCR curve includes the following steps. First, the test sample 400 is placed on the test platen 402. Thereafter, a temperature of the test platen 402 is changed and small currents in mA level are respectively applied to the first conductive trace and the second conductive trace, so as to measure corresponding voltages of the first conductive trace and the second conductive trace with the probe 408 and calculate corresponding resistances of the same. Accordingly, the first TCR curve and the second TCR curve are obtained.

In more details, the method of establishing the first TCR curve and the second TCR curve includes the steps of:

(1) placing the test sample 400 on the test platen 402;

(2) changing a temperature of the test platen temperature 402 to a temperature, wherein the temperature is equal to temperatures of the first conductive trace and the second conductive trace of the test sample;

(3) respectively applying small currents in mA level to the first conductive trace and the second conductive trace at the temperature, so as to measure voltages of the first conductive trace and the second conductive trace with the probe 408 and calculate corresponding resistances of the first conductive trace and the second conductive trace; and

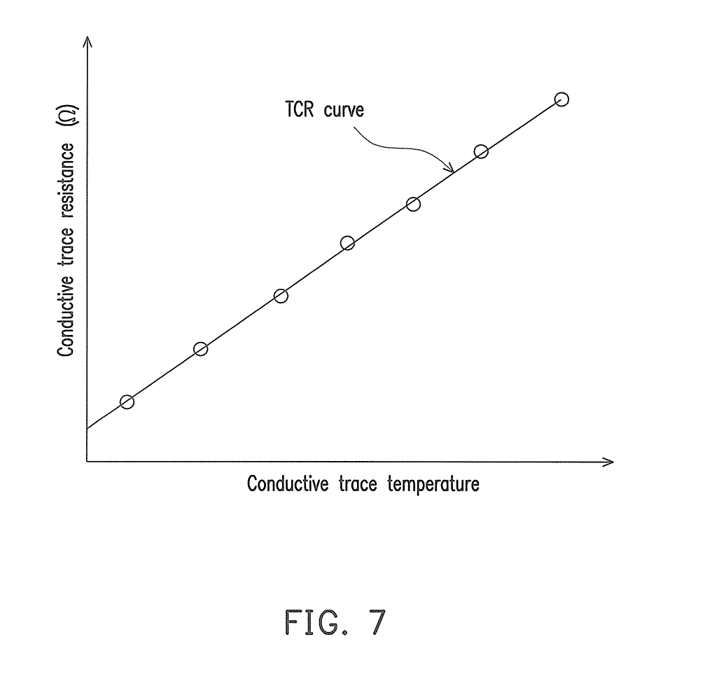

(4) repeating the steps (2) and (3), plotting the resistances of the first conductive trace at the temperatures against the temperatures of the test platen 402 to obtain the first TCR curve of the first conductive trace, and plotting the resistances of the second conductive trace at the temperatures against the temperatures of the test platen 402 to obtain the second TCR curve of the second conductive trace. FIG. 7 schematically illustrates the first TCR curve of the first conductive trace.

Afterwards, a first current (I₁) is applied to the first conductive trace to measure a first voltage (V₁) of the first conductive trace, and a second current (I₂) is applied to the second conductive trace to measure a second voltage (V₂) of the second conductive trace. The first current (I₁) and the second current (I₂) are in the order of tens of mA (>10 mA). The first current (I₁) and the second current (I₂) can be the same or different from each other.

Next, a first thermal power (P₁) and a first electrical resistance (Ω₁) of the first conductive trace and a second thermal power (P₂) and a second electrical resistance (Ω₂) of the second conductive trace are calculated by formula (1) and formula (2),

P=I×V (1)

Ω=V/I (2)

wherein P is a thermal power, Ω is an electrical resistance, I is a current and V is a voltage.

Then, a first temperature (T₁) of the first conductive trace is obtained according to the first electrical resistance (Ω₁) using the first TCR curve, and a second temperature (T₂) of the second conductive trace is obtained according to the second electrical resistance (Ω₂) using the second TCR curve.

Thereafter, a backside temperature (T_{c}) of the substrate is measured with the temperature sensor 406.

Afterwards, a first thermal resistance (R₁) of the first conductive trace and a second thermal resistance (R₂) of the second conductive trace is calculated by formula (3), wherein a thermal resistance of the conductive plug is obtained from a thermal resistance difference between the first thermal resistance (R₁) and the second thermal resistance (R₂),

R=(T-T_{c})/P (3)

wherein R is a thermal resistance, T is a conductive trace temperature and P is a thermal power.

Next, the calculated difference between the first thermal resistance (R₁) and the second thermal resistance (R₂) is compared with a gold data to evaluate integrity or thermal performance of the conductive plug. In an embodiment, the golden data is provided by computational simulation. In another embodiment, the golden data is provided by measuring a test structure of a single qualified and completed sample. In yet another embodiment, the golden data is provided by measuring test structures of a statistically meaningful number of samples.

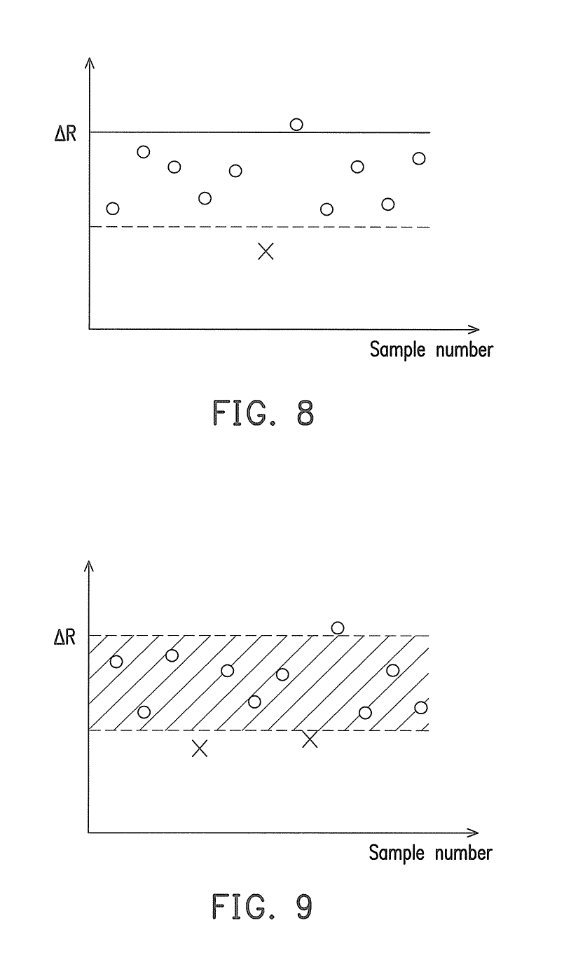

FIGS. 8 and 9 illustrate methods and possible embodiments for determining the performance of conductive plugs (e.g. TSVs). In FIG. 8, the solid line is generated by using computational simulation or measuring a single qualified and completed sample. The dash line corresponds to the minimal integrity-acceptable level (obtained by using computational simulation or measuring small-scale samples). When the measurement data is above the dash line, the sample is qualified for TSV integrity. When the measurement data is below the dash line, the sample is unqualified for TSV integrity.

In FIG. 9, the slash region represents a qualified range generated by measuring large-scale samples. When the measurement data is above the slash region, the sample is unqualified for TSV integrity. When the measurement data is within or higher the slash region, the sample is qualified for TSV integrity. The large-scale samples can be 10, 15, 20, 30 or more samples depending on the population number of samples.

In summary, the configuration of conductive plugs and the corresponding positions of the conductive traces are designed in the test structure. Because the TCR performance is an intrinsic physical property of a conductive material, namely, the same materials have the same TCR performance. Therefore, by pre-measuring the TCR performances of the measured conductive traces, a trustable TCR database can be established and used for later temperature measurement rapidly. By using the TCR database, the measurement period can be substantially shorten, and thus the test structure and the coupled method can be developed for in-line inspection. Besides, the method with the test structure can measure the thermal resistance difference between the first trace and the second trace before the test wafer is thinning, the difference value refer to the TSV (conductive plug) integrity. Therefore, just to diagnose the thermal resistance difference if meets the defined expectation value or not, one can easily knows the measured TSVs structures are perfect, or they are with seam/void inside the TSV filled material. Compared with the conventional measurement concepts which detecting the TSVs integrity when the wafers are thinned or even are stacked, the method of this disclosure provides a benefit to avoid unnecessary wastes for cost and time by taking out the disqualified wafer in a very early stage of IC processes.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A test structure, comprising:
a substrate;
at least one conductive plug, disposed in the substrate;
a first conductive trace, disposed on the conductive plug; and
a second conductive trace, disposed on the substrate, wherein the first conductive trace and the second conductive trace have the same material and the same shape.

2. The test structure of claim 1, wherein the substrate has a first area and a second area, and the conductive plug does not penetrate through the substrate.

3. The test structure of claim 2, wherein the first conductive trace and the second conductive trace are disposed on surfaces of the substrate respectively in the first area and the second area.

4. The test structure of claim 1, wherein the first conductive trace and the second conductive trace are disposed on surfaces of the substrate.

5. The test structure of claim 4, wherein the first conductive trace and the second conductive trace are adjacent to each other.

6. The test structure of claim 5, wherein the first conductive trace and the second conductive trace are arranged correspondingly.

7. The test structure of claim 6, wherein the first conductive trace and the second conductive trace are arranged in parallel.

8. The test structure of claim 1, wherein the first conductive trace is physically connected to the conductive plug.

9. The test structure of claim 1, wherein the first conductive trace is not physically connected to the conductive plug.

10. The test structure of claim 9, wherein a shortest distance between the first conductive trace and the conductive plug is less than or equal to 10 μm.

11. The test structure of claim 9, wherein the first conductive trace has a plurality of conductive rings, and each conductive ring surrounds the corresponding conductive plug.

12. The test structure of claim 11, wherein two test pads are respectively disposed at two ends of each of the first conductive trace and the second conductive trace, and the conductive rings are disposed between the two test pads of the first conductive trace.

13. The test structure of claim 11, wherein a central axis of the conductive plug passes through a ring centre of the conductive ring.

14. The test structure of claim 9, wherein the at least one conductive plug comprises a plurality of conductive plugs, and the conducive plugs are disposed beside the first conductive trace.

15. The test structure of claim 14, wherein the conductive plugs are arranged in rows, and the first conductive trace is disposed on a top surface of the substrate between the rows of the conductive plugs.

16. The test structure of claim 1, further comprising an insulating layer disposed between the conductive plug and the substrate, between the first conductive trace and the substrate and between the second conductive trace and the substrate.

17. The test structure of claim 1, wherein the first conductive trace and the second conductive trace each have at least two test pads, and a measurement tool is used to measure a thermal resistance of the conductive plug.

18. The test structure of claim 17, wherein the measurement tool comprises:
a test platen having a probe;
a temperature sensor disposed in the test platen;
a temperature controllable member for changing a temperature of the test platen; and
a camera disposed above the test platen.

19. The test structure of claim 1, wherein a material of the conductive plug comprises metal.

20. The test structure of claim 1, wherein a material of the substrate comprises silicon.

21. The test structure of claim 1, wherein the conductive plug is a through silicon via (TSV) or a via.

22. The test structure of claim 1, wherein the first conductive trace and the second conductive trace are linear or serpentine.

23. A measurement method of a test structure, comprising:
providing a test sample, wherein the test sample comprises a substrate, at least one conductive plug, a first conductive trace and a second conductive trace;
establishing a first temperature coefficient of resistivity (TCR) curve of the first conductive trace and establishing a second TCR curve of the second conductive trace;
applying a first current (I₁) to the first conductive trace to measure a first voltage (V₁) of the first conductive trace, and applying a second current (I₂) to the second conductive trace to measure a second voltage (V₂) of the second conductive trace;
obtaining a first thermal power (P₁) and a first electrical resistance (Ω₁) of the first conductive trace and a second thermal power (P₂) and a second electrical resistance (Ω₂) of the second conductive trace;
obtaining a first temperature (T₁) of the first conductive trace according to the first electrical resistance (Ω₁) using the first TCR curve, and obtaining a second temperature (T₂) of the second conductive trace according to the second electrical resistance (Ω₂) using the second TCR curve;
measuring a backside temperature (T_{c}) of the substrate; and
obtaining a first thermal resistance (R₁) of the first conductive trace from the first temperature (T₁), the first thermal power (P₁) and the backside temperature (T_{c}), and obtaining a second thermal resistance (R₂) of the second conductive trace from the second temperature (T₂), the second thermal power (P₂) and the backside temperature (T_{c}), wherein a thermal resistance of the conductive plug is obtained from a thermal resistance difference between the first thermal resistance (R₁) and the second thermal resistance (R₂).

24. The measurement method of claim 23, wherein the first current (I₁) and the second current (I₂) are the same or different from each other.

25. The measurement method of claim 23, further comprising comparing the thermal resistance difference with a gold data to evaluate integrity or thermal performance of the conductive plug.

26. The measure method of claim 25, wherein the golden data is provided by computational simulation.

27. The measure method of claim 25, wherein the golden data is provided by measuring a test structure of a single qualified and completed sample.

28. The measure method of claim 25, wherein the golden data is provided by measuring test structures of a statistically meaningful number of samples.

29. The measurement method of claim 23, wherein a method of establishing the first TCR curve and the second TCR curve comprises steps of:
(1) placing the test sample on a test platen;
(2) changing a temperature of the test platen to a temperature, wherein the temperature is equal to temperatures of the first conductive trace and the second conductive trace of the test sample.;
(3) respectively applying small currents in mA level to the first conductive trace and the second conductive trace at the temperature, so as to measure voltages of the first conductive trace and the second conductive trace and calculate corresponding resistances of the first conductive trace and the second conductive trace; and
(4) repeating the steps (2) and (3), plotting the resistances of the first conductive trace at the temperatures against the temperatures of the test platen to obtain the first TCR curve of the first conductive trace, and plotting the resistances of the second conductive trace at the temperatures against the temperatures of the test platen to obtain the second TCR curve of the second conductive trace.

30. The measurement method of claim 29, wherein a temperature sensor is disposed in the test platen to detect the temperature of the test platen, and a temperature controllable member is provided for controlling the temperature of the test platen.

31. The measurement method of claim 30, wherein the temperature controllable member comprises a thermostat chamber, a hot plate, an oil-bath tank or a combination thereof.

32. The measurement method of claim 23, wherein the first conductive trace and the second conductive trace are disposed on surfaces of the substrate.

33. The measurement method of claim 23, wherein the test sample comprises the test structure that comprises:
the substrate;
the at least one conductive plug, disposed in the substrate;
the first conductive trace, disposed on the conductive plug; and
the second conductive trace, disposed on the substrate, wherein the first conductive trace and the second conductive trace have the same material and the same shape.

34. The measurement method of claim 23, wherein the first thermal power and the first resistance of the first conductive trace and the second thermal power and the second resistance of the second conductive trace are obtained from below formulae:
P=I×V, and
Ω=V/I,
wherein P is a thermal power, Ω is an electrical resistance, I is a current and V is a voltage.

35. The measurement method of claim 23, wherein the first thermal resistance of the first conductive trace and the second thermal resistance of the second conductive trace are obtained from below formula:
R=(T-T_{c})/P,
wherein R is a thermal resistance, T is a conductive trace temperature and P is a thermal power.
